(19) United States
(12) Patent Application Publication
(10) Pub. No.: US 2001/0046304 A1
(43) Pub. Date: Nov. 29, 2001

(54) System and method for selective control of acoustic isolation in headsets

(76) Inventor: Rodger H. Rast, Rancho Cordova, CA (US)

Correspondence Address: Rastar Corporation, 11292 Coloma Rd. Suite L, Gold River, CA, 95670, US

(21) Appl. No.: 09/841,713

(22) Filed: Apr. 24, 2001

Related U.S. Application Data
(60) Provisional application No. 60/199,283, filed on Apr. 24, 2000.

(51) Int. Cl. H04R 5/00; H03F 21/00

(52) U.S. Cl. 381/74; 381/26; 381/370; 381/120

(57) ABSTRACT

An apparatus and method for providing controlled acoustic isolation within various forms of headsets. The invention provides manual and automatic mechanisms for changing the amount of acoustic isolation provided by the headsets. Sounds in the environment that the user wishes to be made aware of can be programmed into a set of stored sound selection characteristics. In response to correlation of the stored sound characteristics with sounds in the external environment the headset decreases acoustic isolation by coupling signals from one or more external microphones to the audio conversion elements within the earpieces. Alternatively, the apparatus can respond to sounds to be blocked by increasing acoustic isolation. A manual control may be activated by the user to decrease acoustic isolation at their discretion.

### CROSS-REFERENCE TO RELATED APPLICATIONS

This application claims priority from U.S. provisional application Ser. No. 60/199,283 filed on Apr. 24, 2000.

### STATEMENT OF FEDERALLY SPONSORED RESEARCH OR DEVELOPMENT

Not Applicable

### REFERENCE TO A MICROFICHE APPENDIX

Not Applicable

### BACKGROUND OF THE INVENTION

1. Field of the Invention

This invention pertains generally to headsets and more particularly to an apparatus and method of providing headsets with sound selective acoustical isolation from the external environment.

2. Description of the Background Art

A number of situations exist in which an individual is acoustically isolated from an external environment. The isolation often results in inefficiency or inconvenience, but in other cases it may place the individual, or others nearby, at risk of bodily harm. One primary isolation situation arises from the use of headsets. A wide variety of traditional headsets exist for noise abatement or for listening to an audio source, or communication. Headsets utilized for noise abatement are often constructed as simple passive non-electronic “ear-muff” style devices that block noises within a high ambient acoustic environment. Audio headsets are ubiquitous today for the reproduction of audio sources, in particular, music. Approximately twenty six million (26×10⁶) audio headsets were sold in the year 2000. In addition, headsets are utilized for maintaining communication in a high ambient noise environment, such as in an aircraft cockpit, stadium, and so forth. Generally these headsets have earpieces which either fit over each ear, or are positioned upon each ear and retained in position by a headstrap. Hearing protection headsets are used in high noise environments, such as factory floors, flight decks of aircraft carriers, airport crews, rifle ranges, and in any environment in which the ambient acoustics could prove damaging over time to the hearing of a party within that environment. Audio source headsets are often referred to as “headphones”, or “stereo headphones” and they allow a party to listen to an audio source while being acoustically isolated from the external environment. Audio source headsets are most often used for listening to music, such that the individual wearing the set of headphones may listen to music without being disturbed by nearby ambient sounds (sounds, talking), or the wearer may listen to audio at high decibel volume levels without unduly disturbing others. The numerous lightweight open-air headsets on the market provide reduced acoustic isolation between the listener and the environment, and provide the aforementioned benefits to a more limited extent. Often headphones are utilized in applications for communicating between parties while blocking out sounds of the external environment, such as headphones used by pilots and other flight crew members, and coaches. Headsets are often further equipped with noise cancelation circuitry which introduces a negative environmental noise feedback signal (opposing phase) into the audio source being received, so that the ambient noise is further attenuated and thus acoustic isolation of the wearer from the environment increases without a concomitant increase in the pressure directed between the earpieces on the skull of person wearing the headphones (often commonly referred to as “head-clamping” pressure). It will also be appreciated that some personnel wear headphones strictly for noise abatement to provide hearing protecting within a high ambient noise environment. The intent within each of these headphones is to place an acoustical barrier between the ears of the individual and the sounds within the external acoustic environment. When wearing headphones, especially of the closed cup variety, the wearer is tuned out from the external environment; which indeed is largely the intent.

It should be appreciated, however, that being isolated from every sound within the external acoustical environment can often be inconvenient, or even dangerous. A flight crew member may be unable to hear the siren of an emergency vehicle, a scream, a shout, or an associate loudly calling his/her name, while a party listening to music may miss an important phone call, be unable to hear the door bell, or miss their name being called out. Furthermore, the nonselective nature of the majority of noise cancelation devices provides insufficient attenuation of bothersome noises, such as the roar of an aircraft APU, while it strives to attenuate all external sounds.

Therefore, a need exists for the development of methods for controlling acoustic isolation, so that important events are not missed and non-important noises can be properly identified and ignored. The sound selective acoustic isolation provided in accordance with the present invention satisfies that need, as well as others, and overcomes deficiencies in previously known techniques.

### BRIEF SUMMARY OF THE INVENTION

The present invention of an apparatus for sound selective acoustic isolation provides a number of benefits for users of audio related devices. By way of example the apparatus is exemplified as an environmentally responsive apparatus which is acoustically coupled to the ear(s) of a wearer to provide sound selective acoustical isolation from the environment. The apparatus is typically worn by and acoustically coupled to a user, referred to as the wearer. The acoustical isolation being characterized by the amount of sound attenuation in decibels which occurs as a result of the acoustical coupling of the device to the ear(s) of a wearer. An apparatus and method are described by which the acoustic isolation of the user is modified either manually based on user input, or automatically based on the sounds registered within the external environment and correlated to a set of stored sound characteristics.

Manual changes in acoustic isolation are provided in response to activation of a selection device attached to the headset, wherein the isolation of external sounds is decreased to improve the ability of the wearer to hear the external sounds. The changes in acoustic isolation may be controlled by a signal conditioning circuit, or signal processor, capable of selectively conditioning and routing external sound signals from an associated microphone to the audio conversion device within the earpiece. The manual change in acoustic isolation may be coupled with attenuation of incoming audio signals, such as music programming, or communications, so that the ability of the user to hear the external environment is improved. Attenuation of incoming audio signal preferably exceeds twenty decibels (20 dB). Preferably the selection device comprises a button on the exterior of the earpiece, or headset, that changes the acoustic isolation for only a short period of time, sufficient to allow the user to be alerted to conditions within the external environment.

In automatic mode the apparatus monitors acoustics within the environment against a set of selection criterion and upon finding a match, changes the mode of the headset wherein the amount of acoustical isolation provided is altered temporarily, or until a “reset condition” is received. Automatic changes in acoustic isolation may be similarly coupled with attenuation of the incoming audio signals, as well as the generation of alerts, matching sound “echos”, and so forth to further enhance user cognition of the external environment.

The apparatus is readily embodied within various forms of headsets, such as audio, communication, noise abatement, noise cancelation, and so forth. The term headset is utilized herein as this is the most common configuration for an apparatus to be acoustically coupled to a single wearer. A headset generally comprises a pair of earpieces that are capable of being retained in a position proximal the ear of a wearer. Typically, headsets (or headphones) are utilized for modifying the personal acoustic environment for a single wearer, such as in the case of listening to an audio program source, maintaining communication (such as between pilot and copilot), blocking external sounds, enhancing external audio, and so forth. It will be appreciated, therefore, that the apparatus referred to as a headset may be configured in various mechanical configurations, such as mounted as earpieces within a helmet, single sided headset, earbuds, and so forth.

The environmentally responsive headsets exemplified in the present invention are capable of changing isolation mode in response to a manual trigger, or automatically in response to matching a sound from the external environment with a stored element of sound characterization information which is programmed within the apparatus. Sounds from the external environment are preferably registered by a microphones, with one microphone attached, or integrated, into the exterior of each earpiece. Each microphone converts the received external sound energy to an external sound signal. The mode change of the apparatus generally comprises altering the level of acoustical isolation accorded the wearer by the headset. The mode of the headset may be changed by any of a number of mechanisms, for example, by temporarily routing external sound to earpieces (a “hearthrough mode”), replaying the detected sound (temporally displaced sound—an “echo back”), generating an alert signal (“user alert tone”), attenuating the sound by augmenting active noise cancelation with selective sound acoustical isolation (“block matched sound”), amplifying the ambient sounds after extracting spurious noises, accentuating spoken sounds (drop noise floor while amplifying speech highlights and formants), combinations of the preceding modes, and so forth. Furthermore, if the headset is configured for listening to a programmed sound, such as that being received over a wired connection, or wireless receiver, then the audio amplitude of the programmed audio source may be temporarily attenuated, or disconnected, such that the external sound may be more easily discerned by the wearer.

The selective acoustical isolation provided by the present invention preferably augments the operation of active noise cancelation circuitry within the headset to provide a number of additional benefits. It will be appreciated that noise canceling headphones also require the incorporation of a signal processing circuit coupled to one or more microphones so that the signal registered by the microphone(s) is modified into a negative feedback signal which modifies the program audio signal being received to thereby reduce the apparent receipt of noise acoustically coupled through the housing of the headset. The present invention increases headset safety and convenience by providing a hearthrough mode for the headset wearer, while allowing the wearer to select which sounds are to be heard and which are to be blocked.

The apparatus of the present invention is capable of retaining information about acoustic events (stored sounds) to which external acoustic events (external sounds) may be correlated. For simplicity, this retained information is often referred to as “stored sounds”, or “sound characterizations”, however, it is to be recognized that these “stored sounds” may comprise any combination of sound representations, sound characterizations, sound related algorithms, sound correlation programming, sound scripting, sound signaturing, along with additional methods of storing information about audio waveforms.

One aspect of the present invention is a “hearthrough” mode which routes the acoustics of the environment, preferably at a user selected amplification level, for some period of time to the headset wearer when a hearthrough trigger occurs. The hearthrough trigger may comprise the manual activation of a hearthrough button by the wearer, or by automatic sound detection within the apparatus. In automatic sound detection a signal processing circuit receives signals from one or more microphones, or similar acoustic conversion devices that are preferably incorporated on the exterior portions of the earpieces, or otherwise attached to the headset. The signal processing unit compares the microphone signals against a set of stored selection criterion and upon finding a match alters the amount of acoustical isolation provided by the headset, and/or provides an alerting audio signal to the wearer. It is anticipated that the wearer will typically choose to have the headset temporarily change to a hearthrough mode which may be augmented with sound echo, alerts, and so forth. The wearer is thereby directly provided with audio from the external environment.

The sounds to be correlated may be loaded into the apparatus as elements within a set of programmed sound selection criterion by way utilizing the apparatus to record sounds, or characteristics sounds, which are to be correlated. Many of the sounds for which the user desires reduced acoustic isolation from the environment will be unique to their particular environment, for example their spoken name, the sound of the doorbell, and so forth. Alternatively, preprogrammed sounds may be selected for the selection criterion, loaded from a storage media such as a CD-ROM, or downloaded into the unit, either directly, as a sound, as a set of sound characterizations, as a program entity (algorithm), or as a combination thereof. For example, a single complex selection criterion of “siren” may comprise an algorithm that is capable of discerning a wide variety of common sirens in use. Utilizing this as a preprogrammed algorithm, or a downloaded algorithm would provide a broad discernment of sirens without the need to record one or more specific siren sounds.

Preferably, the unit is configured so that it can be programmed with an audio stream from a source, such as the telephone, or audio from the Internet. When set in a program download mode, the audio source is started and the unit detects, interprets the incoming data, and converts the data to a programmatic entity which provides the desired sound discernment. A simple, albeit bandwidth inefficient, method of tonal code communication may be found in the use of DTMF, wherein sets of dual tones comprise the digits 0-9. It will be recognized that the speed at which digital data may be communicated as audio for an acoustically coupled unit is generally limited to approximately 2400-9600 baud. Aside from actual sound snippets, however, the data being loaded can comprise scripts and other sound related descriptions that can be encoded in less space than individual instructions for a DSP chip. To provide convenience to the user, a library of sounds may be provided, such as over the Internet, or from a CD, wherein the user can select prerecorded sound patterns, sound characterizations, and algorithms to suit their needs. It should, however, be appreciated that the simpler preprogrammed functions of the device may be adequate for a large percentage of intended applications. Alternatively, the apparatus of the present invention may be configured with a conventional jack or similar mechanism through which programming may be received.

To increase the accuracy of sound discernment it is preferable that the user select a sound “type” prior to recording a sound, options may include such types as general sound, speech, loud sounds, repetitive sounds, alarms, telephone rings. The apparatus is thereby capable of extracting proper sound characterization from the sound being “recorded” from the environment. The improved characterization allows for greater discernment accuracy relative to wearer purpose. As an example, consider that correlation performed for the spoken sound “Robert” can be discerned from the external environment in a speaker independent manner utilizing speech recognition characterization of the sound. In contrast, if the sound were to be stored only as a general sound it would not be characterized as speech, wherein speaker independence is lost and discernment would be restricted to a very narrow interpretation.

A wide range of selection criterion may be used upon which to correlate audio signals received from the external environment. The environmental audio may be analyzed by numerous current methods, including parametric analysis, waveform comparisons, Fourier analysis, and in a larger context voice recognition. The selection criterion provides the ability for the signal processing unit to discern a variety of environmental acoustics, which by way of example and not of limitation comprise: alarms, screams, horns, screeching brakes, phones ringing, spoken phrases (i.e. “Hey!”, “Hello”, “Wearer's Name”, “Help”), along with additional acoustic patterns.

According to one aspect of the invention, the user can program the headset to recognize specific sounds within their specific environment. When the signal processing unit within, or attached to the headset, recognizes the environmental audio as matching the criterion, then the mode of the headset is changed in response. The preferred method of changing the mode comprises changing the level of acoustical isolation provided by the headset to the wearer. For example, one preferred method delivers environmental audio to the wearer during a predetermined interval by amplifying the signal from the microphone and playing it over the speakers within the earpieces. Preferably, any incoming audio source, such as music over a wired or wireless connection, is attenuated or disconnected during the period of time the environmental audio is being played. The specific sounds to be recognized (correlated) with the external environment may be contained within the headset as a prerecorded sound, or as a sound that is recorded by the user from the target environment. The repertoire of triggering sounds can therefore be modified according to the conditions under which the wearer wants to be alerted, or interrupted.

In the case of hearing protection headsets (providing noise abatement) implemented according to the present invention; the external audio is attenuated by the earpieces, and optionally a noise canceling circuit within the headset, until the sound being received by the signal processing unit correlates with one or more of the stored selection criterion, at which time the mode of the headphone changes so that the wearer is made aware of the event associated with the stored selection criterion. One preferred method of changing the mode of the headphone is to temporarily couple the sound received from the microphone to the audio transducers, or speakers, within the headset earpieces. The wearer, therefore, is alerted and can clearly discern the danger themselves. The sound can be augmented, preferably depending on the duration, and nature of the sound being recognized, by playing back a recorded version of the precise received segment of received sound (an “echo”) which was correlated with the stored selection criterion. A number of alternatives may be similarly produced, such as playing the recorded sound associated with the stored selection criterion, or the playing of audio alert signals by themselves or in combination with the aforementioned sounds.

Once a correlation occurs of a sound selected for hearthrough, the wearer is preferably provided with the environmental sounds for a period of time, such as three to five seconds (3S -5S), so that they may properly analyze the external environment to assess the situation. The wearer may at this time press a “hearthrough” button on the headset to continue listening to the environment. It will be appreciated that the “hearthrough” button would provide a similar result as removing the headset, however, it may be performed far more quickly and easily than taking off, holding the headsets, and then subsequently restoring them upon the ears.

The present invention may also be utilized within headsets which receive an audio channel, such as music, or communications, which is converted to sound within the earpieces to which the wearer is listening. The signal processing unit operates in a similar manner to the aforesaid hearing protection headset, however, when a correlation is detected between the environmental sounds and the stored sound parameters, the audio channel is switched off or attenuated so that the external environmental sounds may be heard. The attenuation of the audio channel sound source is preferably in excess of twenty decibels (20 dB).

An object of the invention is to decrease both inconvenience and attendant safety risks for persons exposed to uncontrolled acoustic isolation.

Another object of the invention is to increase the safety and convenience of headsets utilized for noise abatement, communication, and sound reproduction.

Another object of the invention is to provide an individual with the ability to selectively control the acoustical isolation between themselves and their acoustic environment.

Another object of the invention is to provide a wearer with reduced acoustical isolation from selected external sounds that sufficiently correlate with one or more stored sounds for which the user should not be isolated.

Another object of the invention is to provide a wearer with increased acoustical isolation from selected external sounds that sufficiently correlate with a one or more stored sounds for which the user is to be isolated (blocked).

Another object of the invention is to provide an apparatus having sound selective acoustic isolation which augments the benefits derived from various forms of active noise cancelation circuitry.

Another object of the invention is to allow user programming of environmental acoustics against which external sounds are to be compared to trigger changes in the isolation provided by the acoustic barrier.

Another object of the invention is to provide alerts to the wearer in response to the detection of selected sounds within the external environment.

Another object of the invention is to provide a manually operated activation mechanism that changes the mode to one of decreased acoustic isolation, wherein the wearer can listen to the external environment without the necessity of removing headsets.

Another object of the invention is to provide the capability to record sounds and patterns of sound recognition for which a headset mode change is to take place upon detection.

Another object of the invention is provide a mechanism wherein the user is capable of indicating a sound “type” prior to recording of a correlation sound, so that sound discrimination may be improved.

Another object of the invention is to allow the wearer to listen to the external environment for a period of time after a stored hearthrough sound is correlated with a sound occurring in the environment.

Another object of the invention is to provide a display upon which programming of the headset may be indicated.

Another object of the invention is to provide audio feedback as to the recorded correlation sound such that the user can easily make recording selections.

Another object of the invention is to provide a headset having externally directed microphones and surrounding structures which are capable of providing directional sound, similar to that of unaided ears, while in hearthrough mode.

Further objects and advantages of the invention will be brought out in the following portions of the specification, wherein the detailed description is for the purpose of fully disclosing preferred embodiments of the invention without placing limitations thereon.

### BRIEF DESCRIPTION OF THE DRAWINGS

The invention will be more fully understood by reference to the following drawings which are for illustrative purposes only:

FIG. 1 is a perspective view of a headset according to an embodiment of the present invention having external microphones and programming buttons, and shown configured for listening to audio programming.

FIG. 2 is a flowchart of sound discrimination according to the present invention.

FIG. 3 is a schematic of selective sound discrimination circuitry according to an embodiment of the present invention.

FIG. 4 is a facing view of a user interface according to an aspect of the present invention, shown with a display, manual selectivity mechanism, manual hearthrough button, and interface buttons.

FIG. 5 is a flowchart of main loop functions according to an aspect of the present invention, showing segmented sound triggering.

### DETAILED DESCRIPTION OF EMBODIMENT(S)

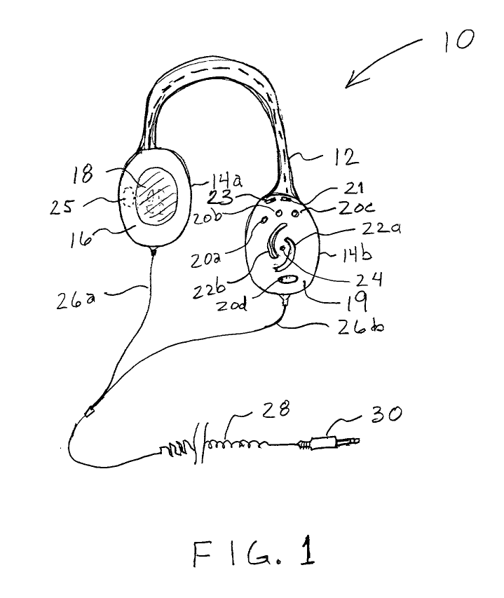

Referring more specifically to the drawings, for illustrative purposes the present invention is embodied in the apparatus generally shown in FIG. 1 through FIG. 5. It will be appreciated that the apparatus may vary as to configuration and as to details of the parts without departing from the basic concepts as disclosed herein.

FIG. 1. is a headset 10 according to an embodiment of the present invention whose audio attenuation of external audio sounds can be selectively changed in response to the correlation of those external sounds with sounds and sound characterizations stored within the headset apparatus. The headsets are exemplified for listening to an audio source over a wired connection, however, it will be appreciated that the present invention is applicable to wireless headphones, communication headsets, noise abatement headsets, headsets incorporated into headgear such as helmets, single ear headsets, earbud style devices, and so forth. The headset 10 is shown comprising an earpiece positioning member 12, earpieces 14a, 14b, with cushioned inner faces 16, an inner cup portion 18 which retains an audio annunciator directed toward, and acoustically coupled to, the ear canal. An exterior surface 19 comprises control buttons 20a-20d, programming switch 21, audio collection grooves 22a, 22b, power switch 23, microphone 24, and hidden enablement switch 25.

The audio collection grooves 22a, 22b and/or ridges which surround the microphone preferably mimic the acoustical function of the structures surrounding the exterior of the human ear, wherein sound is redirected toward the ear canal. In this way the response of the microphones may be optimized and configured to provide a peripheral field of response similar to the ear of the wearer such that the user can discern directional characteristics of sound when the headsets are configured to listen to the external environment. It will be appreciated that conventional active noise cancelation headsets have no need of these ear-fold structures, since they do not provide the wearer with the ability to listen to the external environment—that is unless the headsets are removed from the head of the wearer. The earpieces of the headphones are shown having wires 26a, 26b leading to a joined coiled wired 28 upon which a stereo phono-plug 30 is attached. It will be appreciated that the configuration of the headset may vary using different earpieces and that the positioning member 12 is optional and depends on the structure of the earpieces.

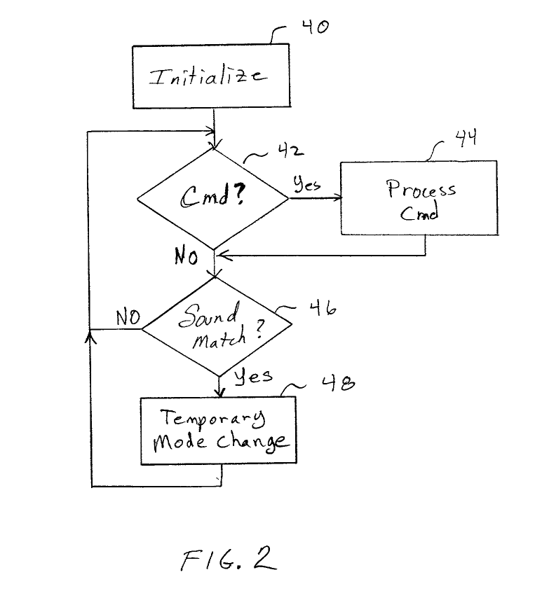

FIG. 2 is a flowchart of basic sound discrimination within the headsets of the present invention. The flowchart assumes that a series of sounds and sound patterns to be discriminated has previously been programmed. Upon power-up of the sound discriminator, such as by use of a power-on switch or the detection of head compression by hidden detection switch 25 of FIG. 1, the circuit is initialized at block 40 wherein the hardware and sounds are prepared for discerning the external events. A check is made to detect command entry at block 42, because the user at any time may elect to program a new sound or alter the mode characteristics of the headset. If a command entry is detected, such as the pressing of a button, then a command processing routine is entered, block 44, which interfaces with the user. Segments of sounds from the external environment are continually compared with the sounds and sound characteristics programmed in the sound correlation unit of the headset. To speed discernment, a small segment of audio is compared with all the stored trigger conditions, and upon meeting a first phase of correlation, the discernment process continues to check further portions of the sound against the stored sounds and characteristics. If the external sound correlates with the programmed sound at block 46, then the mode of operation of the headphone is changed at block 48 to that which has been programmed by the user. It will be appreciated that mode changes should generally comprise changing the amount of acoustical isolation from the environment. Such as by entering a hearthrough mode wherein sound registered by the microphones is conditioned and directed to the audio annunciators within the earcups. Additionally, the audio source being listened to may be either attenuated, or disconnected, such that the amplified external sounds from the microphones may be more clearly heard by the wearer. It will be appreciated, however, that the wearer may alternatively, or additionally be alerted to the correlated sound in a number of ways, such as alerts, and playing of the correlated sound, or the recorded correlation sound.

Alternatively, when the correlated sound is one selected as a sound to be blocked by the headset, the mode change can provide enhanced attenuation of the pattern of sound in a number of ways. The sound pattern matching may be utilized to modulate an active noise cancelation circuit on headsets so equipped. Upon detecting the sound to be blocked, the headset may increase the selected level of noise cancelation from a low, or intermediate value, to a higher level of noise cancelation. The noise cancelation algorithms themselves can also accept the sound pattern as input, wherein the noise cancelation may be tuned to the sound to be blocked. In this way the noise cancelation becomes “selective sound noise cancelation” and is capable of providing high degrees of isolation to selected acoustic signature patterns without the necessity of attempting to cancel all external noise. It will be appreciated that the user can, therefore, configure an active noise cancelation circuit to attenuate all sounds by a given amount, while using the selective attenuation provided by the present invention to specifically attenuate (block) sounds which correlate to the stored sound.

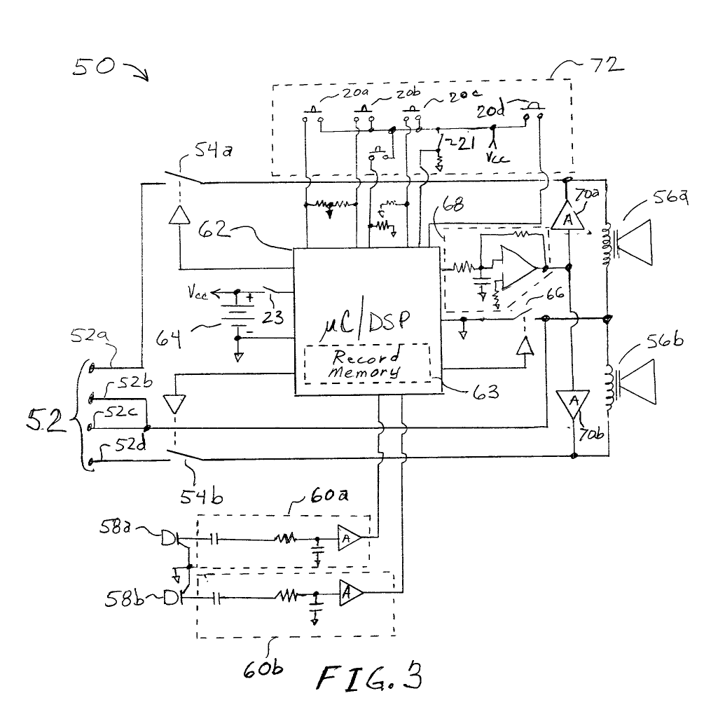

FIG. 3 is a simplified schematic of the electronics 50 for the environmentally responsive headphones according to an embodiment of the present invention. Audio source connections 52a-52d provide an analog audio channel which is routed through a pair of switches 54a, 54b to conventional audio conversion devices 56a, 56b, such as speakers. When listening to the audio source, the switches 54a, 54b are in the closed position. Microphones 58a, 58b, or similar audio conversion devices, convert sounds within the external acoustical environment to electrical signals which pass through the conditioning circuitry 60a, 60b into analog-to-digital converter (ADC) inputs of a combined digital signal processor and microcontroller 62 which contains an internal program store (ROM), random access memory (RAM), and has the ability to store sound waveforms, sound characteristics, and sound profiles 63, to which the external sounds are to be correlated. Power for the DSP/microcontroller is exemplified as battery power 64, although the power may be derived from a variety of sources, such as the bias voltage or signal voltage as provided on the input audio source connections 52a-52d. The DSP/microcontroller 62 is capable of processing the audio signals from the microphones 58a, 58b and correlating these signals with a set of audio selection criterion which are stored in the sound characterization memory 63. When the microphone input correlates with the stored parameters, such as detecting the word “Hello!”, then the DSP/microcontroller 62 within the present embodiment preferably switches off the input sources by opening switches 54a, 54b, engaging switch 66 to tie into the ground of the DSP with ground for the speakers 56a, 56b, and then outputting via a digital-to-analog converter the sound collected from the microphones to an amplifier circuit 68 which is then buffered by amplifiers 70a, 70b to the separate channels of the earpiece speakers 56a, 56b. It will be appreciated that the correlation of sound and speech patterns is well known in the art. It will be recognized that the sound from the microphones is thereby selectively passed through to the listener when it correlates to a sufficiently high degree with the stored audio parameters. Once correlation occurs, the environmental sounds collected from the microphones are preferably passed through to the headset wearer for a period of time, for example three to five to seconds (3 S-5 S), during which the user can decide to press and hold the “hearthrough” button 20d as shown in FIG. 1, to keep listening to the environmental audio, or allow the duration to time out and return to listening to their original programming. The use of the “hearthrough” button to control hearthrough may be configured in a variety of ways. One such way is to interpret a quick button press as a change of state; from non-hearthrough mode to a short period of hearthough, or from a hearthrough mode back to normal non-hearthrough mode. A button press of an intermediate duration, can be used to indicate that hearthrough mode should be entered for a slightly longer than conventional interval, regardless of original state. A button press of long duration may then be interpreted as a signal to lock the headset into hearthrough mode until a quick press of the “hearthrough” button occur.

To aid in understanding the correlation of external sounds with sounds stored within the apparatus, an example follows for a stored spoken sound of “hello”. Speech recognition characteristics relating to the spoken sound of the word “Hello!” are stored within the headset apparatus and the characteristics are compared with the sounds registered by the microphones and fed to the signal processing unit. Thereafter, if the spoken word “Hello” is registered by the microphone from the external environment, the headphone preferably switches to a hearthrough mode to communicate environmental sounds to the wearer. In addition, as it will be appreciated that the spoken word “hello” was blocked during correlation, the sound “hello” received from the environment and just correlated may be played, in essence as an echo upon which an additional alert tone may be superimposed to alert the wearer that a hearthrough correlation has occurred and to indicate that the replayed sound has been reproduced (thereby suffering from a temporal shift) so that the user will not be confused if the echo of “hello” is heard in concert with continued verbiage from the person who uttered the “hello”.

The headset contains a series of buttons including a power switch 23 which allows switching off all power to the headset to conserve power. In addition, an enable switch 25 as shown in FIG. 1, may be built into one or more of the earpieces so that when the headsets are placed on the wearers head the headset correlation functions will activate, providing the power switch is set to on, at which time preferably a beep, tone sequence, or the voiced phrase is played over the earpieces to alert the wearer that the environmentally responsive functionality is active. The wearer may toggle from listening to the audio channels and listening to the environmental acoustics by alternately pressing button 20d on the lower portion of the headsets. It will be appreciated that a manual mode change may be activated by various touch patterns as well as by the wearer themselves saying a word or phase which has been programmed or recorded for discrimination. While listening to an audio source, such as music, the wearer may press button 20d and elect to listen to the environment; pressing of button 20d again would return the headset to listening to the musical audio source. In this manner the wearer may elect to hear their environment when they so elect, as when responding to a visual cue. The wearer may also press the mode button after the three to five seconds (3 S-5 S) of environmental acoustics have been played following a sound correlation, such as “Hello!”, so as to continue listening to the environment. By way of example, the user may program a sound into the headsets by assuring power switch 23 is ON, setting programming switch 21 from normal mode into program mode, and then holding down one of the program channel buttons 20a-20c while the programmed sound is occurring, for example: they have their coworker call out “Hello!”, or ring their phone. Preferably the headsets are preprogrammed to respond to specific commands or tone sequences; which may include “Help”, the cadence and sound of a phone ringing, the sound of a doorbell, or a siren. In addition pressing of a program button when the program switch is in normal mode preferably causes the headset to play the stored sound over the headset so that the user may verify which sounds have been stored. It will be recognized that numerous interfaces can be implemented for programming and control of the headsets without departing from the inventive teachings.

It will be appreciated that audio headphones are often equipped with a volume control to allow the wearer to set the audio level played over the earpieces. The headset may additionally contain a sensitivity control that allows the user to set the sound level required in order to trigger the correlated response. In the example of the word “Hello!” the sensitivity adjustment would select how loud, or alternatively how accurate, the sound would need to be in order to trigger the correlation response.

The headset may also be equipped with a feedthrough control wherein the user can select the amount of external environment acoustics which are feedthrough for their hearing. Example: sounds are amplified differentially as determined from sound parameters and sound levels and so forth. The user thereby can set the dB amount of isolation they desire from the surrounding environment.

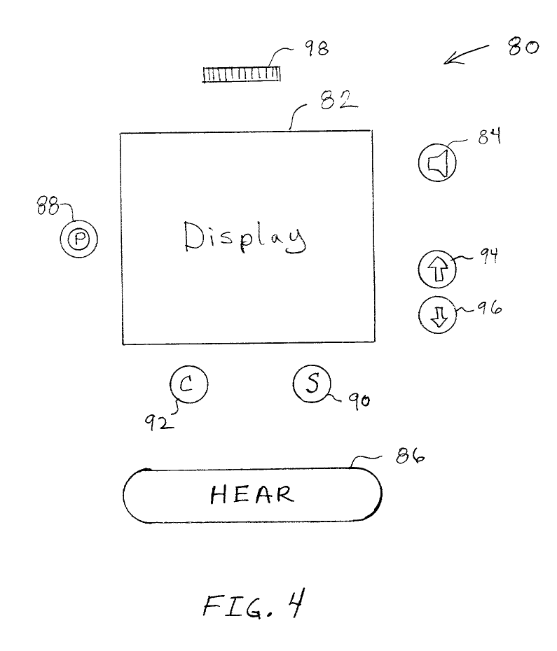

Referring now to FIG. 4 a user interface 80 is shown for an environmentally responsive headset according to an aspect of the present invention. The interface allows the user to program the desired functionality of the headsets, such as operation, modes changes, as well as the selection of preprogrammed sounds, and both the recording and downloading of sounds and sound characterization information for correlation with the external environment. A display 82 provides for the generation of non-audio feedback to the user. Display 82 may be configured as a small graphical LCD display, such as found on a cellular phone. A listen button 84 allows the user to listen to any selected programmed sound or set of programmed characteristics, wherein determinations of their use can be assessed. A “hearthrough” button 86, provides for a manual activation of the hearthrough function wherein, external sounds picked up by the microphones are amplified and played within the earcups, preferably in concert with attenuating the audio amplitude of the programmed sound source. It will be appreciated that headsets may be configured with only the manual selection of hearthrough, such as provided by button 86, without departing from the teachings of the present invention. A program button 88 allows for the activation of sound recording, or characterization. It should be recognized that the duration of sound recorded is selected by the user in response to the retention of the program button, such that the user can select the amount of sound which is to be correlated prior to the occurrence of a mode change by the headset. Program button 88 is shown recessed to prevent inadvertent programming. A select button 90 allows selection of an item within a scrolling list shown on display 82. A clear button 92 allows for clearing a selected response, and for traversing in reverse order the prior screens. A set of up 94 and down 96 scroll buttons allow moving a selection up and down within the display for making user choices. A scrolling wheel 98, provides for altering the sensitivity of the sound discrimination circuit to the programmed sounds. The sensitivity preferably is a combination of both the amplitude of the sounds as well as the accuracy of the sounds in relation to the sounds and sound characteristics stored, and recorded within the environmentally responsive headset.

Referring now to Table 1, by way of example and not of limitation, lists a series of commands which are preferably implemented within the headset. The user is preferably capable of selecting all operating parameters of the selective acoustical isolation apparatus through the user interface. The method of powering the device may be selectable depending on the specific form of headset being utilized, for example, power may in some cases be drawn from a wired connection that has a bias voltage, or from a rectified portion of the signal. In addition, the mode of activation and shutdown, for conserving battery power should be selectable. The mode of selective acoustical isolation to be provided by the headset apparatus as well as the sounds can preferably be programmed. A set of default characteristics which are to apply to the sounds which are to be heard in the environment may be selected. These may be overriden for any particular sound, however, the specification of a default reduces unnecessary selections by the user. Similarly, default characteristics for how to treat sounds that are to be blocked. It will be appreciated that sounds to be blocked may be ongoing “events”, wherein the selective acoustical isolation device continues to apply the attenuation to the given sound. The headset preferably is received by the user with a wide variety of pre-programmed sound characterizations, such as a telephone ring, smoke alarm siren, the spoken word “Hello”, and so forth. These sound characterizations are configured to provide matching with a variety of devices that need not produce the exact same sound. For example, it will be appreciated that telephone ringing cadence in the united states is fixed, wherein the discernment of ringing may be generally provided by a preprogrammed sound selection criterion. The user preferably can select which of these they wish to trigger a reduction in acoustical isolation. Similarly the user can select from preprogrammed sounds they wish to block, such as a car burglar alarm. The user may also record sounds that are specific to their environment which are to be used to modify the isolation provided by the headset. Prior to programming a sound that the user wants to be alerted to, the user may enter information about how to process the sound. For example, the user can select how the headset is to respond to the given sound, for instance should hearthrough be activated so that they may listen to the external environment, should the detected sound be repeated (echo mode), should an alert be generated. To improve correlation, the type of sound to be correlated can be selected by the user prior to recording. By selecting the type, the apparatus can store the proper sound characteristics to provide adequate correlation. For example sound characterization data stored for a spoken word is different than characterization data stored for a sound, or an alarm sound. The user can preferably select the required accuracy necessary for the unit to consider the external sound correlated with the stored sound. The user can also preferably select what is to be done with the audio source being received. The headset may be utilized for listening to music or for communication, wherein the headset is receiving signals that are being converted to audio by the audio conversion devices within the earpieces. The user can select if these signals are to be attenuated in response to the detection of a hearthrough match, for example, none (no attenuation), block (completely block), −10 dB (attenuate by 10 dB), −20 dB (attenuate by 20 dB), −40 dB (attenuate by 40 dB). The duration of hearthrough can preferably be selected by the user, such as a duration in seconds. The relative volume to which hearthrough is to be configured is preferable set by the user. The user may then select to record a given sound, or to perform an audio “download” of sounds from an audio player device. User selection with regard to blocking selected sounds are similar in nature to the above although more limited in scope. It should be readily appreciated that the aforementioned user options are described by way of example, wherein a particular environmentally responsive headset that provides selective acoustic isolation may provide a different set of options without departing from the teachings of the present invention.

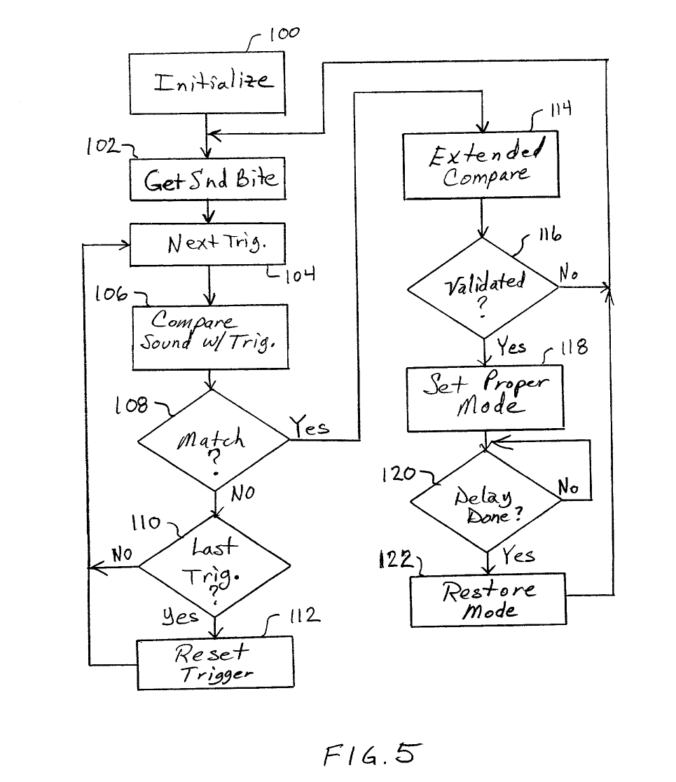

FIG. 5 is a flowchart of the method of correlating the external sounds and characteristics with programmed or recorded sounds or characteristics and changing the mode of the headset accordingly. The flowchart exemplifies a processor main loop, wherein command processing is considered to be in a separate module whose execution is in response to a processor interrupt. The electronics for the environmentally responsive headset are initialized for proper operation at block 100. This may take place after power up, or in response to the headsets being in a state of operation, such as positioned on the head of a user. The sound correlation method described is similar to that utilized in performing text string searches, in that the first character is compared for a match, and upon matching the first character, each subsequent character is checked until either a mismatch is found, or the search string is fully matched, at which time a match is returned. In the flowchart, the sound or characteristics thereof are matched a piece at a time. Preferably, distinctive sound elements, or characteristics are searched for thereby reducing the amount of processor overhead. The sound being recorded from the microphones is considered to be placed in a circular buffer, such as by a periodic interrupt, wherein the processor is capable of operating on information from the buffer. A sound bite is retrieved from the buffer at block 102. It will be appreciated that the sound bite may comprise waveforms, waveform characteristics, or characteristics of sound, depending on the algorithms that are being utilized for providing correlation. A pointer to the correlation sound, or trigger condition, is advanced at block 104 and the sound bite is compared at block 106. If the sound does not match this particular correlation sound (stored sound selection criterion) then a check is made to determine if this is the last correlation sound in the list at block 110. If this is not the last correlation sound, then processing returns to block 104 which advances the correlation sound, trigger condition, to the next condition, and sound comparisons continue. The pointer to the correlation sound is reset at block 112 when all correlation sounds have been checked against the sound bite. Upon the sound bite matching the correlation sound as detected at block 108, execution reaches an extended comparison routine, wherein subsequent portions, or characteristics, of the external sound are compared with subsequent portions of the stored correlation sound at block 114. A determination is made at block 116 as to whether the sound detected in the environment matches the correlation sound, or characteristics. If the sound is found not to match the correlation sound, then execution returns to processing the sound bite with other correlation sounds, as shown at block 102. If the sound is validated then block 118 is reached which sets the mode of the headset according to the configuration as set by the user. For example, if the correlation sound was set for a sound that the user wished to be alerted to then the sound being received by the microphone may be amplified and output as audio by the audio transducers in the earpiece so that the user can hear the sound. The audio volume of programmed sounds being output from the audio transducers is preferably attenuated to a given decibel level in relation to the sound detected, so that the wearer can easily hear the external sounds. In addition, the wearer may be alerted with additional warning tones, or a playback of the sound taken from the environment or the correlation sound. If the mode change is a temporary one, such as to allow the wearer to hear the external environment for a period of time, then a delay is checked for completion at block 120. At the conclusion of the delay the mode of the headset may be restored to the original mode at block 122. It will be appreciated that the preceding flowchart is a simplified description of the sound discrimination program that will allow one of ordinary skill in programming sound discrimination systems to code the program.

It will be appreciated that the invention can be implemented in a variety of ways for a number of applications without departing from the inventive teachings. One somewhat unique example involves the configuration of the headphones for use by infantrymen on the battlefield. The unit can be integrated into a helmet, or worn as a headset. The sound correlation unit being preferably configured for controlled attenuation, selective blocking, of artillery and gunfire to a predetermined decibel level so that hearing is not dulled or damaged, while sounds such as voices, troop movements and so forth are amplified to provide a hearing advantage to the solder. The headset itself would preferably be configured with a radio so that each infantryman may be retained in communication contact, such as with the squad leader. The headset preferably mixes the incoming audio with the ambient sounds so that the radio communication function is realized without the wearer losing audio contact with the environment. Upon detection of selected sounds in the external environment the incoming communication is blocked or attenuated and the external sounds are amplified to improve the safety of the infantryman. In addition, at the time of sound correlation, a radio signal may be forwarded to the squad leader, or otherwise utilized to signal the external event. To enhance the device for use within this application, the mechanical housing which surrounds the microphones should be preferably configured to direct sound in a similar pattern to the human ear, although with perhaps a larger surface area, wherein the wearer could still discern directional characteristics of ambient sounds in a conventional manner. A similar utilization exist for a combat pilot, wherein the headset, typically with the earpieces incorporated into the flight helmet, provides for remote communication, the accentuation of critical audio, and the blocking of select noises, such as the noise of the particular engine. A second example would provide coaches, such as football, with a communication headset that allows them to still hear and communicate with players, while blocking crowd noise. Examples of use abound for those in high ambient noise environments, and those wearing communication headsets, such as pilots. In addition, it will be appreciated that disc-jockeys may find that headsets according to the invention provide the benefits of a studio quality sound reproduction headset while not preventing them from hearing necessary studio sounds, such as telephones, alerts, co-workers, and so forth. Perhaps the most common use may be for those persons wearing headphones to listen to music at work or at home, wherein they will be provided with a studio quality sound experience without the need of worrying about missing telephone calls, alarms, doorbells, or the utterances of another individual such as a spouse. Furthermore, the wearer can listen to the external environment, as triggered by sounds and speech, or as triggered by activating a hearthrough option, such as by pressing a button. The wearer is able to listen to the environment in these instances without the necessity of removing the headset from their head, or turning down the music.

It will be appreciated that the sound selective acoustical isolation system and method may be less preferably adapted for use within electronic and mechanical equipment that produces a high decibel sound output. It will be appreciated that workers in a high noise environment are essentially isolated from various forms of audio communication, such as spoken words, alarm sounds, and sounds which indicate a dangerous condition due to the high intensity of the noise produced by the equipment. The isolation danger is further exacerbated by the wearing of conventional noise protection headsets, the limitations of which have already been described, because the workers are further isolated from sounds associated with a dangerous or safety related issue. The safety of these workers is therefore compromised due to their isolation from the external environment. The present invention may be substantially incorporated within various forms of controllable sound producing equipment to reduce the risk to those persons working nearby. The microphone correlates a stored sound, or set of sound characteristics, such as screams, a siren, a fire alarm, and so forth, with sounds in the environment. After detecting a match the system changes the “acoustic isolation” afforded nearby individuals by causing the noise-producing device to enter a reduced-noise mode, such as by turning off the device, slowing down the speed of the device, or muting audio sound production. It will be appreciated, therefore, that use of a modified version of the present invention within these noisy environments can increase safety and convenience.

Accordingly, it will be seen that this invention can be employed within various equipment, particularly headsets, for a variety of applications in acoustic environments. An analog headset embodiment has been shown and described, however, it will be recognized that digital headsets, which may provide class D output to the audio conversion elements, such as speakers, are anticipated within the invention. Specifically utilizing the invention with a digital input source simplifies the system as audio input is routed through the DSP/microcontroller on the way to the speakers, and power may be derived easily from the digital signal or a bias level embedded within that signal, as well as from battery sources. It will be appreciated that the circuits described for implementing the environmentally responsive headsets are but a single design embodiment to carry out the inventive teachings described, and that one of ordinary skill in the art can render innumerable variations without creative effort.

Although the description above contains many specificities, these should not be construed as limiting the scope of the invention but as merely providing illustrations of some of the presently preferred embodiments of this invention. Thus the scope of this invention should be determined by the appended claims and their legal equivalents. Therefore, it will be appreciated that the scope of the present invention fully encompasses other embodiments which may become obvious to those skilled in the art, and that the scope of the present invention is accordingly to be limited by nothing other than the appended claims, in which reference to an element in the singular is not intended to mean “one and only one” unless explicitly so stated, but rather “one or more.” All structural, chemical, and functional equivalents to the elements of the above-described preferred embodiment that are known to those of ordinary skill in the art are expressly incorporated herein by reference and are intended to be encompassed by the present claims. Moreover, it is not necessary for a device or method to address each and every problem sought to be solved by the present invention, for it to be encompassed by the present claims. Furthermore, no element, component, or method step in the present disclosure is intended to be dedicated to the public regardless of whether the element, component, or method step is explicitly recited in the claims. No claim element herein is to be construed under the provisions of 35 U.S.C. 112, sixth paragraph, unless the element is expressly recited using the phrase “means for.”

TABLE 1
Preferred Command List

Setup-configure use

Options for: Power-off, Display use, Hear button duration, etc.
Alert settings-tone, volume, duration, etc.

Default, Hear-Default settings for sounds to be heard
Default, Block-Default settings for sounds to attenuate
Sounds Prerecorded, Hear: select any from an audio list

(i.e. phone, siren, scream, doorbell, Hello, danger sounds . . .)

Sounds Prerecorded, Block: select any from an audio list

(i.e. car alarm . . .)

Sounds 1 − n:

Mode: Through/Block

IF Through:

Hear by: Through, Repeat, Alert (check box)
Sound type: Spoken/Sound/Sound repetitive/Alarm (select)
Accuracy: required fit of sound (1 − n)
Amplification: (1 − n)
Audio source: NC, Block, −10 dB, −20 dB, −40 dB
Duration: time for pass through (1 − n)
Volume: (1 − n)
Record (start recording)
Download sound/algorithm (start recording)

IF Block:

Accuracy: required fit of sound (1 − n)
Attenuation: (1 − n)
Record (start sound recording)
Download sound/algorithm (start recording)

What is claimed is:

1. A headset for providing selective acoustical isolation to the wearer, comprising:
(a) an earpiece capable of being positioned proximal the ear of a person wearing said apparatus;
(b) an audio conversion device within the earpiece that is positioned so as to be acoustically coupled to the ear canal of said wearer, said audio conversion device configured to receive electrical energy and convert it to sound;
(c) a microphone attached to said earpiece and configured to register the energy of sounds which occur external to the earpiece and to convert the sound energy to an external sound signal;
(d) a selection device attached to said headset capable of being activated by the headset wearer; and
(e) a signal conditioning circuit configured to sufficiently amplify and couple the external sound signal to the audio conversion device in response to activation of the selection device such that the headset enters a hearthrough mode which improves the ability of the wearer to hear external sounds.

2. A headset as recited in claim 1, further comprising a timing mechanism within the headset that automatically deactivates the selection device a predetermined period of time after activation.

3. A headset as recited in claim 1, wherein the selection device comprises a switch activated by contact by the wearer.

4. A headset as recited in claim 1, wherein the headset is configured to receive input signals which are coupled to the audio conversion device, such that the wearer may listen to programming such as music and audio communications that are received within the input signals.

5. A headset as recited in claim 4, wherein the signal conditioning circuit is further configured to attenuate the input signals upon the activation of the selection device so as to improve the ability of the wearer to hear the external environment.

6. A headset as recited in claim 5, wherein the level of attenuation comprises a muting of the input source by at least 20 dB.

7. A headset as recited in claim 1, wherein the signal conditioning circuit comprises a signal processing unit which is further configured to compare the sounds registered by the microphone against a set of stored sound selection criterion, whereupon while the selection device remains inactive and in response to the signal processing circuit discerning a sufficient level of sound matching it conditions and couples the sound registered by the microphone to the audio conversion device within the earpiece such that the ability of the wearer to hear external sounds is responsive to the detection of selected sounds.

8. An apparatus for providing selective acoustical isolation to the wearer, comprising:
(a) an earpiece configured for positioning proximal the ear of a person wearing said apparatus and as a result providing a given number of decibels of acoustical isolation from the external environment;
(b) an audio conversion device within the earpiece that is positioned so as to be acoustically coupled to an ear canal of said wearer, said audio conversion device configured to receive an electrical signal which is converted to sound;
(c) a microphone attached to said earpiece that is configured to register the acoustical energy of external environmental sounds which are converted to an external sound signal; and
(d) a signal processing circuit configured to receive the external sound signal from said microphone which is compared against a set of programmed sound selection criterion, whereupon the amount of acoustic isolation provided by the apparatus is changed in response to a sufficient level of sound matching thereof.

9. An apparatus as recited in claim 8, wherein the change in the amount of acoustic isolation occurs for a sufficient period of time to alert the wearer of conditions in the external environment.

10. A headset as recited in claim 8, further comprising a manually operated selection device mounted on the apparatus which upon activation triggers a reduction in the amount of acoustical isolation provided by the apparatus.

11. An apparatus as recited in claim 8, wherein said audio conversion device is configured for receipt and conversion of a received program signal, such as music or communications, to audio for listening by the wearer.

12. An apparatus as recited in claim 8, wherein the signal processing circuit is configured to record sound characterizations as programmed sound selection criterion upon user activation of characterization recording in approximate temporal synchronization with sounds from the external environment whose sound characteristics are to be programmed.

13. An apparatus as recited in claim 8, wherein the signal processing circuit is configured to allow the user to select programmed sound selection criterion from a preprogrammed set of sound selection criterion.

14. An apparatus as recited in claim 8, wherein the set of programmed sounds comprise characterization information about sounds, referred to as hearthrough sounds, which the listener should be alerted to in response to their occurrence within the external environment, wherein in response to a sufficient level of sound matching between the sounds from the external environment and the hearthrough sounds the acoustical isolation of the apparatus is decreased by applying the external sound signal registered by the microphone to the audio conversion device to reproduce external sounds within the earpiece.

15. An apparatus as recited in claim 14, wherein said audio conversion device is configured for receipt and conversion of a received program signal, such as music or communications, with said program signal being attenuated in response to sufficient matching of the hearthrough sound with sounds registered from the external environment such that the ability of the wearer to listen to the external environment is improved.

16. An apparatus as recited in claim 8, wherein the signal processing circuit is further configured to generate an alerting signal to the audio conversion device to signal the wearer that a sufficient sound match has occurred.

17. An apparatus as recited in claim 8, wherein the signal processing circuit is configured with noise cancelation circuitry to enhance the earpiece acoustical isolation by modifying the output from the audio conversion device with a negative feedback, opposing phase, signal based on sounds registered by the microphone.

18. An apparatus as recited in claim 17, wherein the set of programmed sounds comprise characterization information about sounds, referred to as hearthrough sounds, which the listener should be alerted to in response to their occurrence within the external environment, and wherein the signal processing circuit is configured to reduce the acoustic isolation provided by the noise cancelation circuitry after a hearthrough sound is sufficient matched with a sound from the external environment so as to improve the ability of the wearer to hear the external environment.

19. An apparatus as recited in claim 17, wherein the noise cancelation circuitry is configured to selectively increase acoustical isolation provided by the headset of sound characterization elements contained within the set of programmed sound selection criterion that specify sounds which are to be blocked from the external environment, referred to as a blocked sound, wherein the noise cancelation circuitry specifically enhances its active attenuation of blocked sounds as received from the external environment.

20. A method of providing selective acoustic isolation of a headset wearer from the external acoustic environment, comprising the steps of:
(a) acoustic monitoring of the external environment so that the acoustics are registered by a microphone and converted to electrical signals received by a signal processing circuit;
(b) comparison of the monitored acoustics from the microphones by the signal processing circuit with a stored set of acoustic sound parameters; and
(c) converting the monitored acoustics registered by the microphones into acoustic energy within the headset in response to matches of the monitored acoustics with elements in the stored set of acoustic sound parameters such that the wearer of the headset is made aware of selected external acoustics which are associated to the set of stored acoustic parameters.
